(19) United States
(12) Patent Application Publication
(10) Pub. No.: US 2025/0372489 A1
(43) Pub. Date: Dec. 4, 2025

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Won Chul Do, Seoul (KR); Tae Kyeong Hwang, Incheon (KR); Hee Jun Jang, Chungcheongbuk-do (KR); Jae Yoon Kim, Gyeonggi-do (KR)

(73) Assignee: Amkor Technology Singapore Holding Pte. Ltd., Singapore (SG)

(21) Appl. No.: 19/203,567

(22) Filed: May 9, 2025

Related U.S. Application Data
(60) Provisional application No. 63/652,364, filed on May 28, 2024.

(51) Int. Cl. H01L 23/498; H01L 23/31

(52) U.S. Cl. CPC H01L 23/49816; H01L 23/3135; H01L 23/49866

(57) ABSTRACT

In one example, an electronic device comprises a first substrate comprising a first conductive structure, a first electronic component over a first side of the first substrate and coupled to the first conductive structure, a second substrate over the first substrate and over the first electronic component, wherein the second substrate comprises a second conductive structure, an internal interconnect between the first substrate and the second substrate and coupled to the first conductive structure and the second conductive structure, and an encapsulant between the first substrate and the second substrate and covering a lateral side of the first electronic component and a lateral side of the internal interconnect. A first one of the first substrate and the second substrate comprises a redistribution layer (R D L) substrate, and a second one of the first substrate and the second substrate comprises a laminate substrate. Other examples and related methods are also disclosed herein.

### CROSS-REFERENCE TO RELATED APPLICATIONS

The present application claims the benefit of US Application No. 63/652,364 filed May 28, 2024. Said Application No. 63/652,364 is hereby incorporated herein by reference in its entirety.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device in accordance with one or more embodiments.

FIGS. 2A-21 show an example method to manufacture an electronic device in accordance with one or more embodiments.

FIG. 3 shows a cross-sectional view of an example electronic device in accordance with one or more embodiments.

FIG. 4 shows a cross-sectional view of an example electronic device in accordance with one or more embodiments.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features. The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to a mechanical coupling or an electrical coupling.

### DESCRIPTION

In one example, an electronic device comprises a first substrate comprising a first conductive structure, a first electronic component over a first side of the first substrate and coupled to the first conductive structure, a second substrate over the first substrate and over the first electronic component, wherein the second substrate comprises a second conductive structure, an internal interconnect between the first substrate and the second substrate and coupled to the first conductive structure and the second conductive structure, and an encapsulant between the first substrate and the second substrate and covering a lateral side of the first electronic component and a lateral side of the internal interconnect. A first one of the first substrate and the second substrate comprises a redistribution layer (RDL) substrate, and a second one of the first substrate and the second substrate comprises a laminate substrate. Other examples and related methods are also disclosed herein.

In another example, a method to manufacture an electronic device comprises providing a first substrate comprising a first conductive structure, providing an internal interconnect on a first side of the first substrate and coupled to the first conductive structure, attaching a first electronic component to the first side of the first substrate, providing an encapsulant over the first side of the first substrate and covering a lateral side of the first electronic component and a lateral side of the internal interconnect, and providing a second substrate over the first substrate and over the first electronic component, wherein the second substrate comprises a second conductive structure, wherein the second conductive structure is coupled to the internal interconnect and the and the first electronic component. A first one of the first substrate and the second substrate comprises a RDL substrate, and a second one of the first substrate and the second substrate comprises a laminate substrate.

In a further example, an electronic device comprise a first substrate comprising a first conductive structure, a second substrate comprising a second conductive structure, an first electronic component between the first substrate and the second substrate, wherein a first side of the first electronic component comprises a component interconnect coupled to the first conductive structure, and a second side of the first electronic component is attached to the second substrate, an encapsulant between the first substrate and the second substrate and covering a lateral side of the first electronic component, and an internal interconnect in the encapsulant and coupled to the first conductive structure and the second conductive structure. The first substrate comprises a RDL substrate and the second substrate comprises a laminate substrate.

Other examples are included in the present disclosure. Such examples may be found in the figures, in the claims, or in the description of the present disclosure.

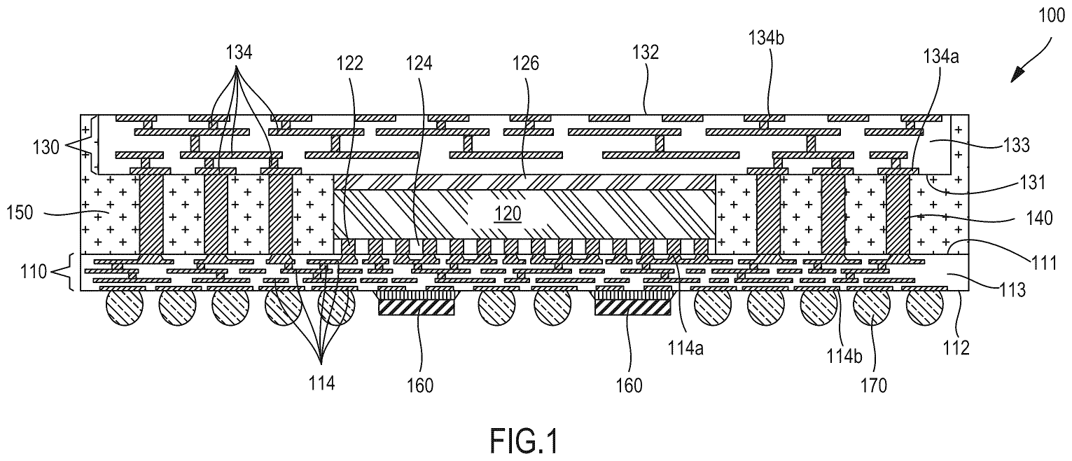

FIG. 1 shows a cross-sectional view of an example electronic device 100 in accordance with one or more embodiments. In the example shown in FIG. 1, electronic device 100 can comprise substrate 110, electronic component 120, substrate 130, vertical interconnects 140, and encapsulant 150.

In accordance with various embodiments, substrate 110 can comprise dielectric structure 113 and conductive structure 114. Conductive structure 114 can include inner terminals 114a along an inner side 111 of substrate 110 and outer terminals 114b along an outer side 112 of substrate 110. Substrate 130 can comprise dielectric structure 133 and conductive structure 134. Conductive structure 134 can include inner terminals 134a along an inner side 131 of substrate 130 and outer terminals 134b along an outer side 132 of substrate 130. In some examples, substrate 110 can comprise a multi-layer redistribution layer (“RDL”) or build-up substrate, and substrate 130 can comprise a multi-layer laminate or preformed substrate.

One or more electronic components 120 can be between substrate 110 and substrate 130. In some examples, electronic component 120 can be coupled to substrate 110. In some examples, component interconnects 122 can couple electronic component 120 to inner terminals 114a of conductive structure 114. In some embodiments, a dielectric material 124 can be between electronic component 120 and substrate 110 and can cover the lateral sides of component interconnects 122. An adhesive 126 can be disposed between electronic component 120 and substate 130. Encapsulant 150 can be between substrate 110 and substrate 130 and in some embodiments encapsulant 150 can cover the lateral sides of substrate 130. Internal interconnects 140 can be in encapsulant 150 and can be coupled to conductive structure 114 of substrate 110 and conductive structure 134 of substrate 130.

In some examples, one or more electronic components 160 can be coupled to outer side 112 of substrate 110. One or more external interconnects 170 can be coupled to outer side 112 of substrate 110. In some examples, external interconnects 170 and electronic components 160 can be coupled to outer terminals 114b of conductive structure 114.

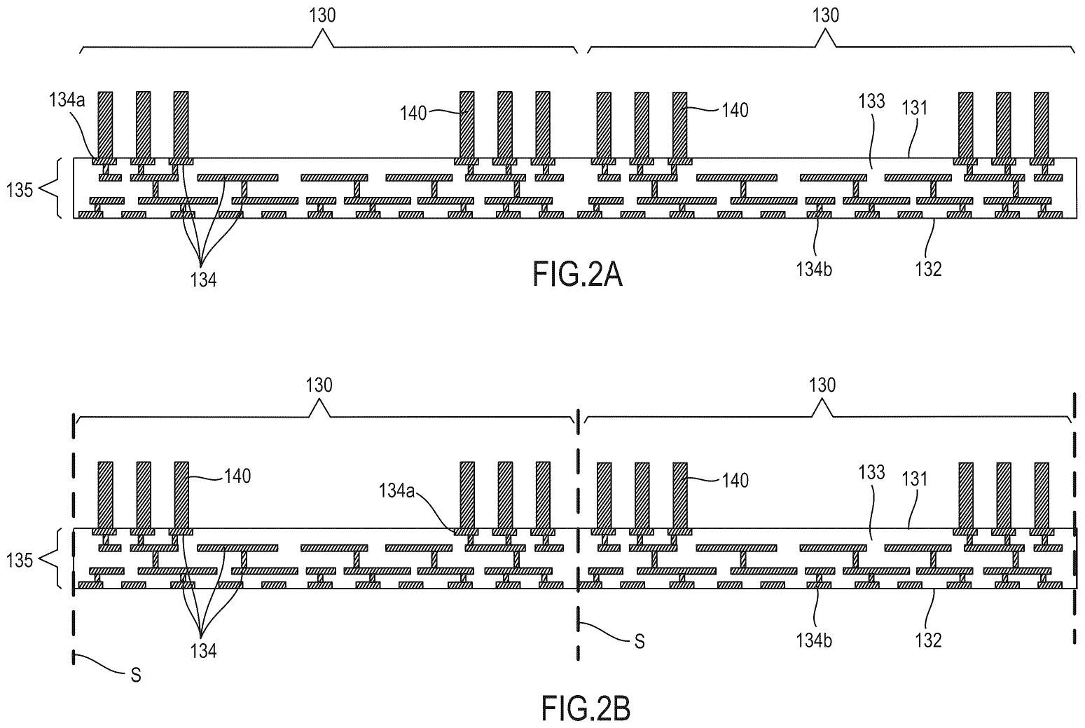

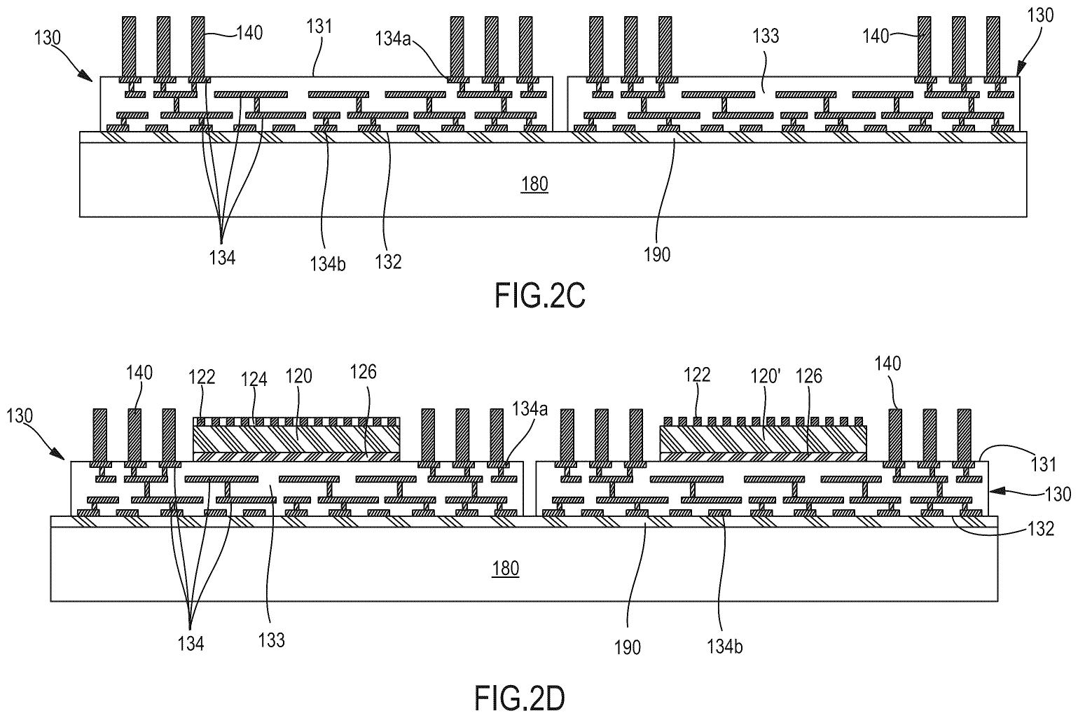

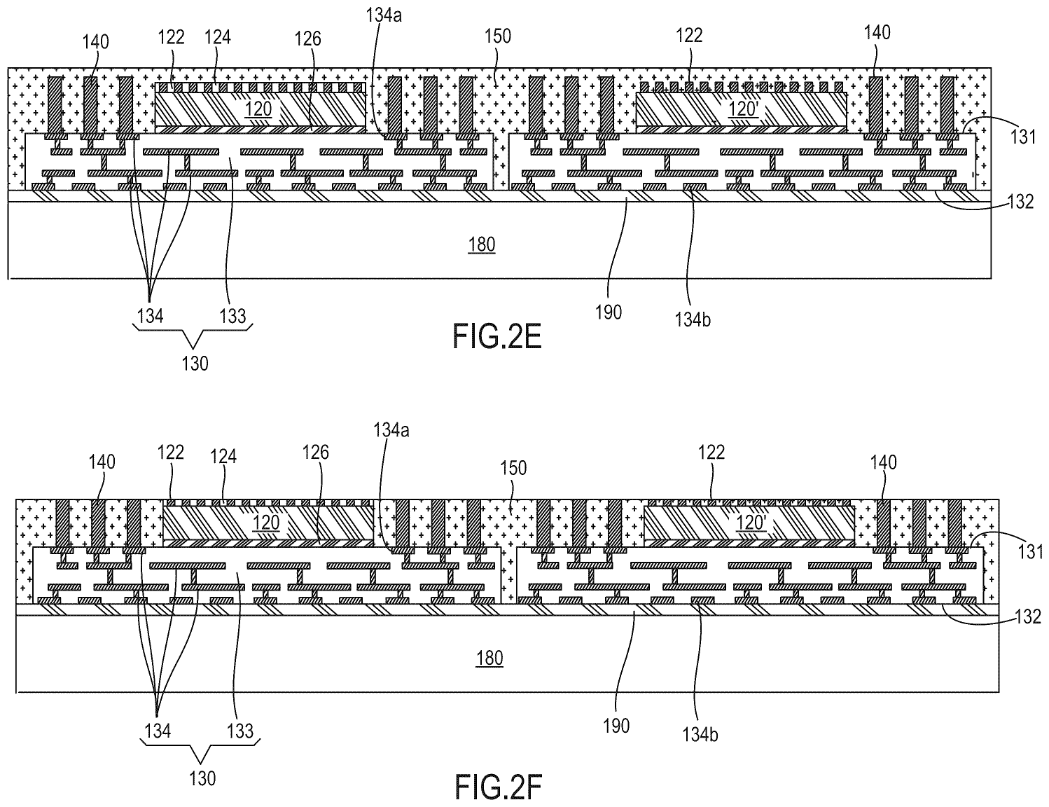

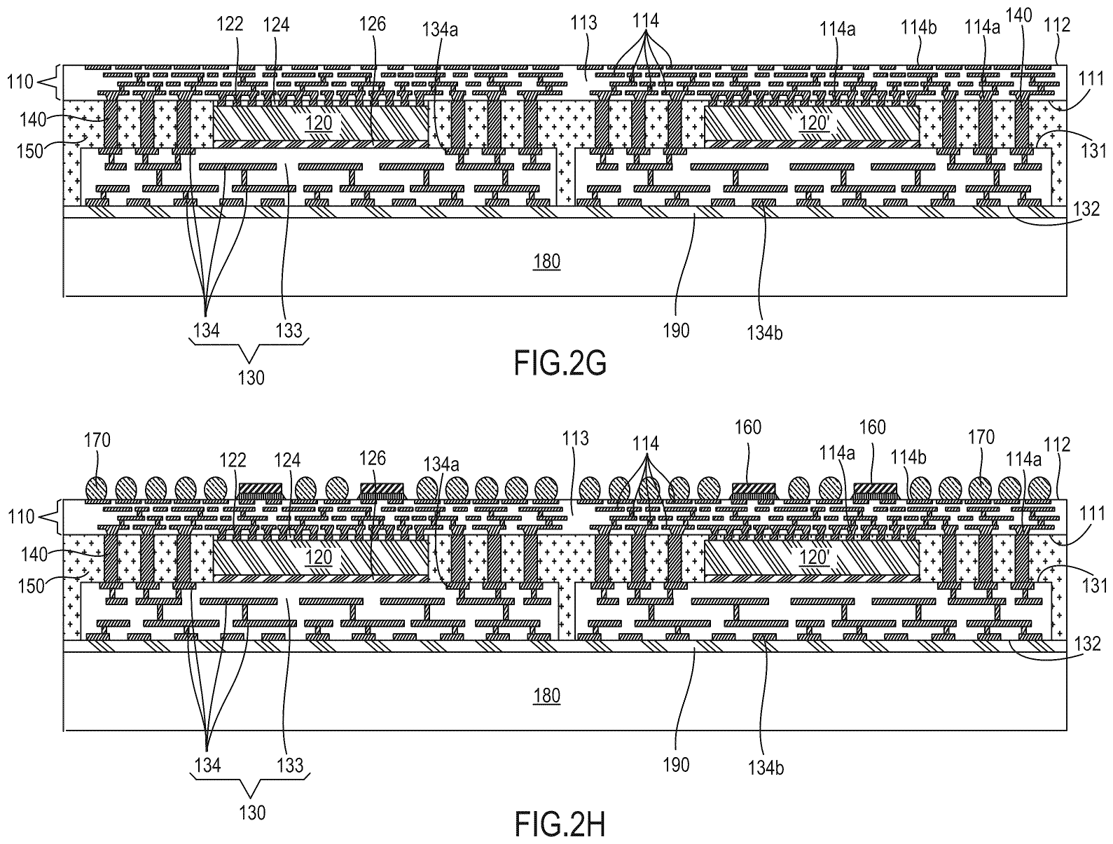

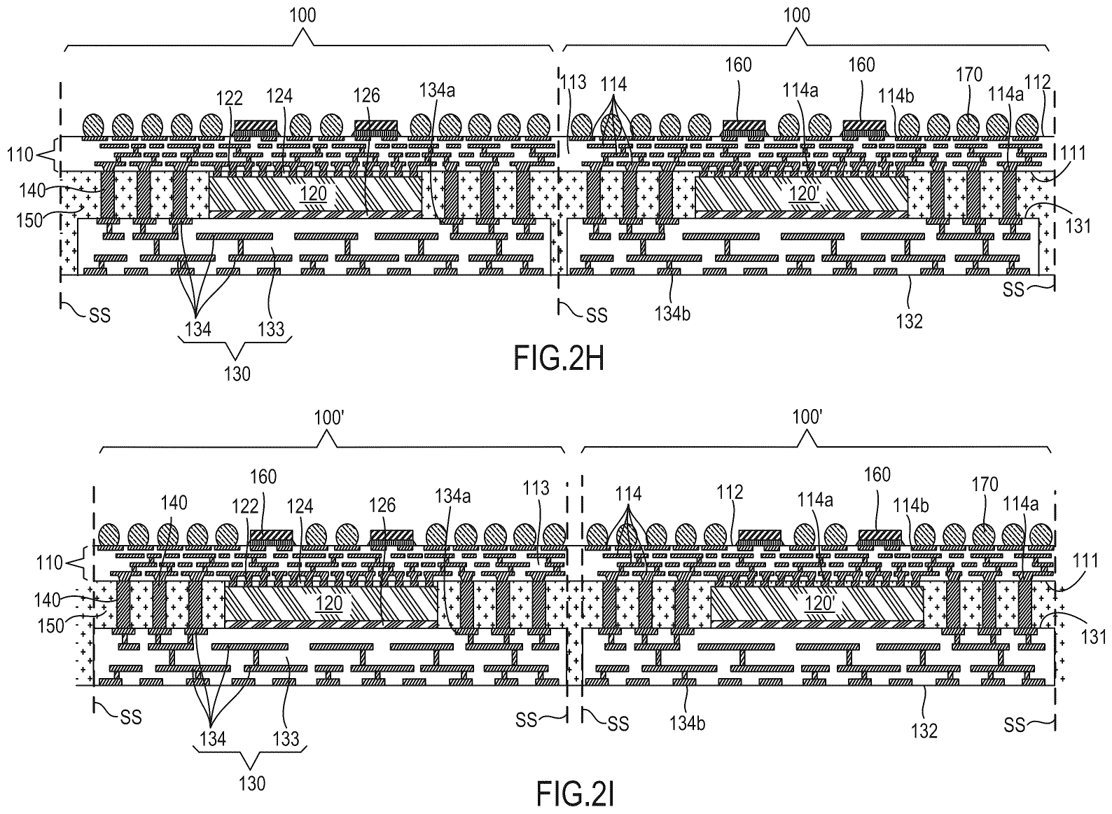

FIGS. 2A-21 show an example method for manufacturing an electronic device, such as electronic device 100 in FIG. 1, using cross-sectional views. FIG. 2A shows a cross-sectional view of electronic device 100 at an early stage of manufacture. In the example shown in FIG. 2A, substrate 130 can be provided. In accordance with various embodiments, substrate 130 can be provided as a strip 135. Substrate strip 135 can include a plurality of adjacent, connected substrates 130.

In accordance with various examples, each substrate 130 can comprise dielectric structure 133 and conductive structure 134. In some examples, dielectric structure 133 can comprise or be referred to as one or more stacked dielectric layers. For instance, the one or more dielectric layers can comprise one or more core layers, polymer layers, pre-preg layers, or solder mask layers stacked on each other. One or more layers or elements of conductive structure 134 can be interleaved with elements or layers of dielectric structure 133. In some examples, dielectric structure 133 can comprise polymer, bismaleimide triazine (BT), polyimide (PI), benzocyclobutene (BCB), polybenzoxazole (PBO), Ajinomoto Buildup Film (ABF), resin, mold compound, ceramic, glass, silicon, or copper clad laminate, or a flame retardant material such as FR4 comprising laminated layers of copper foil and glass fiber fabric. Dielectric structure 133 can maintain the shape of substrate 130 and can structurally support conductive structure 134.

Conductive structure 134 can comprise or be referred to as one or more conductive layers defining signal distribution elements, traces, vias, pads, conductive patterns, conductive paths, wiring patterns, circuit patterns, or under bump metallization (UBM). In some examples, conductive structure 134 can comprise one or more layers of copper (Cu), aluminum (Al), tin (Sn), titanium (Ti), titanium tungsten (TiW), gold (Au), silver (Ag), nickel (Ni), palladium (Pd), or combinations or alloys thereof. The thickness of conductive structure 134 can range from approximately 3 μm to approximately 50 μm. The thickness of conductive structure 134 can refer to the thickness of individual layers of conductive structure 134. Conductive structure 134 can provide electrical signal paths such as vertical paths and horizontal paths through dielectric structure 133.

Conductive structure 134 can comprise inward terminals 134a provided along an inner side 131 of substrate 130, and outward terminals 134b provided along an outer side 132 of substrate 130 that is opposite inner side 131. In some examples, inward terminals 134a and outward terminals 134b can comprise or be referred to as pads, lands, or UBM. Layers and elements of conductive structure 134 can electrically couple inward terminals 134a with outward terminals 134b.

Substrate 130 can comprise a core or be coreless. In some examples, substrate 130 can comprise or be referred to as pre-formed or laminate substrate. Pre-formed substrates can be manufactured prior to attachment to an electronic device and can comprise dielectric layers between respective conductive layers. The conductive layers can comprise, for example, copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising BT or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Other substrates in the disclosure can also comprise a pre-formed substrate.

In accordance with various embodiments, one or more internal interconnects 140 can be provided over inner side 131 of substrate 130. In some examples, internal interconnects 140 can be referred to as internal interconnect structures 140. Internal interconnects 140 can be coupled to conductive structure 134. For example, internal interconnects 140 can be coupled to or can contact inner terminals 134a of conductive structure 130. Internal interconnects 140 can be spaced apart from each other in a row or column arrangement. Internal interconnects 140 can be provided by electrolytic plating, electroless plating, solderless plating, sputtering, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). Internal interconnects 140 can comprise Cu, Al, Sn, Ti, TiW, Au, Ag, Ni, Pd, or combinations or alloys thereof. In some examples, internal interconnects 140 can be preformed structures that are formed prior to being located over substrate 130. Such preformed interconnects can be coupled to inner terminal 134a via a conductive material such as solder or a conductive adhesive. Internal interconnects 140 can comprise plated pillars, preformed posts or pins, vertical wires, bumps, solder-coated-metallic-core-interconnects or other vertical interconnect structure. In some examples, the height of internal interconnects 140 can range from approximately 25 μm to approximately 850 μm, or from approximately 100 μm to approximately 700 μm, or can be equal to or greater than approximately 500 μm, can be equal to or great than approximately 700 μm, or can be equal to or greater than approximately 800 μm. In some examples, the width or diameter of internal interconnects can range from approximately 25 μm to approximately 250 μm, or approximately 50 μm to approximately 150 μm, or can be equal to or less than approximately 100 μm, or equal to or less than approximately 50 μm. It is noted that these are example dimensions for interconnects 140, and the scope of the disclosed subject matter is not limited in these respects.

FIG. 2B shows a cross-sectional view of electronic device 100 at a later stage of manufacture. In the example shown in FIG. 2B, substrate strip 135 is singulated into individual substrate units 130.

In accordance with various examples, singulation of substrate strip 135 can be performed by cutting along scribe lines or saw streets S, thereby separating individual substrates 130 from one another. Singulation can be performed using, for example, mechanical cutting such as sawing, cutting, polishing, or snapping, energy cutting such as laser cutting, plasma cutting, and so on, or chemical cutting such as etching or melting. In some examples, after singulation, internal interconnects 140 can be located about an edge or perimeter area of substrate 130.

FIG. 2C shows a cross-sectional view of electronic device 100 at a later stage of manufacture. In the example shown in FIG. 2C, substrates 130 are provided over carrier 180.

Carrier 180 can comprise a substantially planar support structure. In some examples, carrier 180 can comprise or be referred to as a plate, a board, a wafer, or a panel. For example, carrier 180 can be provided as a round wafer or a square or rectangular panel. In some examples, the width of carrier 180 can range from approximately 100 millimeters (mm) to approximately 300 mm. In some examples, the width of carrier 180 can range from approximately 300 mm to approximately 650 mm. As used herein with numeric values, the term “approximately” can mean+/−5%, +/−10%, +/−15%, +/−20%, or +/−25%. Carrier 180 can support multiple substrates 130 during processing.

In some examples, carrier 180 can comprise a temporary bond layer 190 provided on the upper side of carrier 180. In some examples, temporary bond layer 190 can comprise or be referred to as a temporary bonding film, a temporary bonding tape, or a temporary adhesive coating. For example, temporary bonding layer 190 can comprise a heat release tape or film or an optical release tape or film, wherein the adhesive strength is weakened or removed by heat or light, respectively. The temporary bond layer 190 can facilitate separation of substrates 130 from carrier 180 at a later stage of manufacture.

In accordance with various embodiments, substrates 130 can be coupled to carrier 180 via temporary bond layer 190. Substrates 130 can be located over carrier 180, for example using pick and place equipment. Substrates can be coupled to carrier 180 with inner side 131 and internal interconnects oriented away from carrier 180.

FIG. 2D shows a cross-sectional view of electronic device 100 at a later stage of manufacture. In the example shown in FIG. 2D, electronic components 120, 120′ are provided over substrates 130.

In accordance with various embodiments, electronic components 120 and 120′ can be coupled to inner sided 131 of substrates 130. In some examples, a backside of electronic components 120 and 120′ can be coupled to inner side 131 of substrates 130 using a die attach film 126. Die attach film 126 can be applied to the backsides of electronic components 120 and 120′ or to inner sides 131 of substrates 130. Electronic components 120 and 120′ can be located on substrates 130, for example using pick and place equipment.

Electronic components 120 and 120′ can comprise a front side and a backside opposite the front side. In some examples, the front side can comprise or be referred to as an active side, and the backside can comprise or be referred to as an inactive side. Component interconnects 122 can be provided on front side 121 of electronic components 120, 120′. Component interconnects 122 can be coupled to contact pads on the active side of electronic components 120 and 120′. Component interconnects 122 can comprise or be referred to as bumps, SnPb bumps, leadfree bumps, stud bumps, pillars, posts, or solder-capped copper posts. In some examples, component interconnects 122 comprise Cu pillars. In some examples, component interconnects 122 can be provided by plating, ball-drop, solder reflow, thermocompression, or any other suitable deposition process.

In accordance with various examples, electronic component 120 includes a dielectric material 124 on the front side of electronic component 120. Dielectric material 124 can surround component interconnects 122. An upper side of component interconnects 122, that is a side oriented away from the front side 121 of electronic component 120 can be exposed from dielectric material 124. Electronic component 120′ can be similar to electronic component 120 except with electronic component 120′ being devoid of dielectric material 124.

Electronic components 120 or 120′ can each comprise or be referred to as a semiconductor die, semiconductor chip, semiconductor package, semiconductor device, active component, or passive component. In some examples, electronic components 120 or 120′ can comprise application specific integrated circuits (A SIC), digital signal processors (DSPs), network processors, power management units, audio processors, wireless baseband system-on-chip (SoC) processors, sensors, custom integrated circuits, memory die or packages, or an antenna.

FIG. 2E shows a cross-sectional view of electronic device 100 at a later stage of manufacture. In the example shown in FIG. 2E, encapsulant 150 can be provided over electronic components 120 and 120′, substrates 130, and carrier 180.

In accordance with various embodiments, encapsulant 150 can be deposited on electronic components 120 and 120′, inner side 131 of substrates 130 and the upper side of carrier 180, for example on temporary bonding layer 190. Encapsulant 150 can surround internal interconnects 140, and in some examples encapsulant 150 can contact internal interconnects 140. Encapsulant 150 can be between adjacent substrates 130 and can be coupled to or contact the lateral sides of substrates 130. Encapsulant 150 can flow between and contact the lateral sides of component interconnects 122 of electronic component 120′. Dielectric material 124 can prevent or block encapsulant 150 from contacting the lateral sides of component interconnects 122 of electronic component 120. Encapsulant 150 can comprise or be referred to as a package body, an encapsulating structure, an insulator, a mold, an epoxy molding compound, a resin, a filler-reinforced polymer, a B-stage compressed film, or gel. Encapsulant 150 can be provided by transfer molding, compression molding, liquid encapsulant molding, vacuum lamination, paste printing, film assisted molding, or any other suitable process.

FIG. 2F shows a cross-sectional view of electronic device 100 at a later stage of manufacture. In the example shown in FIG. 2F, a portion of encapsulant 150 can be removed to expose internal interconnects 140 and component interconnects 122.

In accordance with various examples, encapsulant 150 can be removed to expose the upper sides of component interconnects 122 and internal interconnects 140. In some examples, a back grinding or chemical mechanical polish (CM P) and/or etching process can be used to remove encapsulant 150. In some examples, the back grinding, CM P, or etching can also remove a portion of component interconnects 122 or internal interconnects 140. The upper sides of encapsulant 150, component interconnects 122, dielectric material 124, and internal interconnects 140 can be coplanar after the removal step.

FIG. 2G shows a cross-sectional view of electronic device 100 at a later stage of manufacture. In the example shown in FIG. 2G, substrate 110 can be provided over encapsulant 150 and over the exposed component interconnects 122 and internal interconnects 140.

In accordance with various examples, substrate 110 can be provided over encapsulant 150 and can cover the exposed sides of the component interconnects 122 of electronic components 120 and 120′, dielectric material 124, and internal interconnects 140. Substrate 110 can comprise dielectric structure 113 and conductive structure 114. Dielectric structure 113 can comprise or be referred to as one or more dielectric layers interleaved with layers of conductive structure 114. Dielectric structure 113 can maintain the shape of substrate 110 and can structurally support conductive structure 114.

Conductive structure 114 can comprise or be referred to as one or more conductive layers defining signal distribution elements, traces, vias, pads, conductive patterns, conductive paths, wiring patterns, circuit patterns, or UBM. In some examples, conductive structure 114 can comprise one or more layers of Cu, Al, Sn, Ti, TiW, Au, Ag, Ni, Pd, or combinations or alloys thereof. The thickness of conductive structure 114 can range from approximately 3 μm to approximately 25 μm. The thickness of conductive structure 114 can refer to individual layers of conductive structure 134. Conductive structure 114 can provide electrical signal paths such as vertical paths and horizontal paths through dielectric structure 113.

Conductive structure 114 can comprise inward terminals 114a provided along an inner side 111 of substrate 110, and outward terminals 114b provided along an outer side 112 of substrate 110 that is opposite inner side 111. Inward terminals 114a can be coupled to or can contact component interconnects 122 and internal interconnects 140. In some examples, inward terminals 114a and/or outward terminals 114b can comprise or be referred to as pads, lands, vias, or UBM. Layers and elements of conductive structure 114 can electrically couple inward terminals 114a with outward terminals 114b.

In some examples, substrate 110 can be an RDL substrate and can comprise one or more conductive redistribution layers and one or more dielectric layers that are formed layer by layer over electronic components 120 and 120′, interconal interconnects 140, and encapsulant 150. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces. The conductive patterns can be formed using a plating process, for example an electroplating process, an electroless plating process, or a solderless plating process. The conductive patterns can comprise a conductive material, for example copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, PI, BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of one or more inorganic dielectric layers can comprise silicon nitride (Si3N4), silicon oxide (SiO2), or silicon oxynitride (SiON). The one or more inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit the core structure, for example a dielectric material comprising BT or FR4, generally associated with laminate substrates. RDL substrates can be referred to as build-up substrates. In some examples, the minimum line width and line spacing of conductive structure 114 of substrate 110 can be less than the minimum line width and line spacing, respectively, of conductive structure 134 of substrate 130. Conductive structure 114 can electrically couple electronic components 120, 120′ to internal interconnects 140. For example, electronic components 120 or 120′ can be electrically coupled to conductive structure 134 of substrate 130 via conductive structure 114 and internal interconnects 140.

FIG. 2H shows a cross-sectional view of electronic device 100 at a later stage of manufacture. In the example shown in FIG. 2H, external interconnects 170 are provided over substrate 110. In some examples, one or more additional electronic components 160 can be over substrate 110.

In accordance with various examples, external interconnects 170 can be provided over outer side 112 of substrate 110. External interconnects 170 can be coupled to outer terminals 114b of substrate 110. In some examples, external interconnects 170 can comprise Sn, Ag, Pb, Cu, Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 170 can be provided by depositing a conductive material including solder on outer pads 114b through a ball drop method followed by a reflow process. External interconnects 170 can comprise or be referred to as solder balls, bumps, pads, or pillars. In some examples, electronic device 100 can be configured as a land grid array (LGA) and devoid of external interconnects 1470. For example, outer terminals 114b can be configured as the external interconnections for coupling electronic device 100 to a board such as a PCB, or to another electronic device.

In some examples, electronic components 160 can be provided over outer side 112 of substrate 110. Electronic components 160 can be coupled to outer terminals 114b of substrate 110. Electronic components 160 can comprise or be referred to as a semiconductor die, semiconductor chip, semiconductor package, semiconductor device, active component, or passive component. Electronic components 160 can be electrically coupled to electronic components 120 or 120′ via conductive structure 114, and to conductive structure 134 of substrate 130 via conductive structure 114 and internal interconnects 140.

FIG. 2I shows a cross-sectional view of electronic device 100′ at a later stage of manufacture. In the example shown in FIG. 2I, carrier 180 can be removed and singulation can be performed.

In accordance with various examples, singulation can be performed by cutting through saw streets SS disposed around a perimeter of the depicted electronic devices 100′, thereby separating individual electronic devices 100 from one another. Singulation can be performed using mechanical cutting such as sawing, cutting, polishing, or snapping, energy cutting such as laser cutting, plasma cutting, and so on, or chemical cutting such as etching or melting. Singulation can include cutting through substrate 110 and encapsulation 150. In some examples as shown in example electronic devices 100 of FIG. 2H, after singulation encapsulant 150 can be coplanar with the lateral sides of substrate 110 and can remain over or cover the lateral sides of substrate 130. In some examples as shown in example electronic devices 100′ of FIG. 2I, after singulation encapsulant 150 can be coplanar with the lateral sides of substrate 110 and with the lateral sides of substrate 130.

It is noted that although FIG. 1 shows an RDL or build-up substrate 110 and a laminate substrate 130, electronic device 100 can comprise various other combinations of RDL substrates or laminate substrates. For example, substrate 110 and substrate 130 can both comprise RDL or build-up substrates, substrate 110 and substrate 130 can both comprise laminate substrates, or substrate 110 can comprise a laminate substrate and substrate 130 can comprise an RDL substrate.

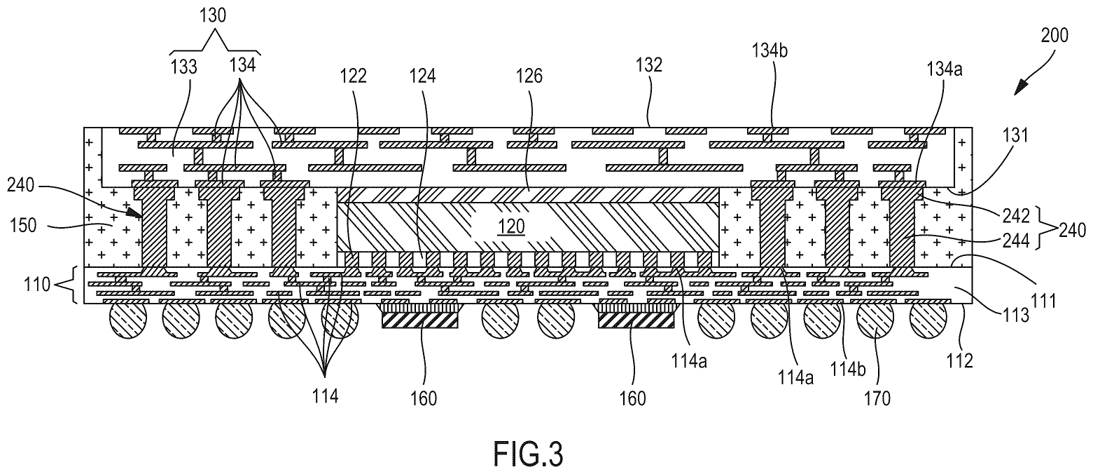

FIG. 3 shows a cross-sectional view of example electronic device 200. Electronic device 200 can be similar to electronic device 100 of FIG. 1, and can include substrate 110, electronic component 120, substrate 130, encapsulant 150, electronic components 160, and external interconnects 170 as previously described.

In accordance with various examples, electronic device 200 includes internal interconnects 240. In some examples, internal interconnects 204 can be referred to as internal interconnect structures 240. Internal interconnects 240 can comprise vertical wires. For example, internal interconnect 240 can include a head or ball bond portion 242 coupled to or contacting inner terminal 134a of conductive structure 134 and a tail or wire portion 244 extending from head portion 242 and coupled to or contacting inner terminal 114a of conductive structure 114. Encapsulant 150 can surround internal interconnects 240. Internal interconnects 240 can provide electrical connection between conductive structure 114 of substrate 110 and conductive structure 134 of substrate 130. In some examples, vertical wire internal interconnects 240 can have a narrower pitch as compared to pillar or post internal interconnects 140. Electronic device 200 can be manufactured using substantially the same method used to manufacture electronic device 100, as shown in FIGS. 2A-21 discussed above. For example, when manufacturing electronic device 200, internal interconnects 240 comprising vertical wires can be coupled to inner side 131 of substrate 130 in place of internal interconnects 140 in FIG. 2A. Removal of the upper portion of encapsulant 150 in FIG. 2F can expose the distal side of tail portions 244, that is the side opposite head portion 242. Inner terminals 114a of conductive structure 114, as provided in FIG. 2G, can be plated on or contacting the exposed distal side of tail portions 244.

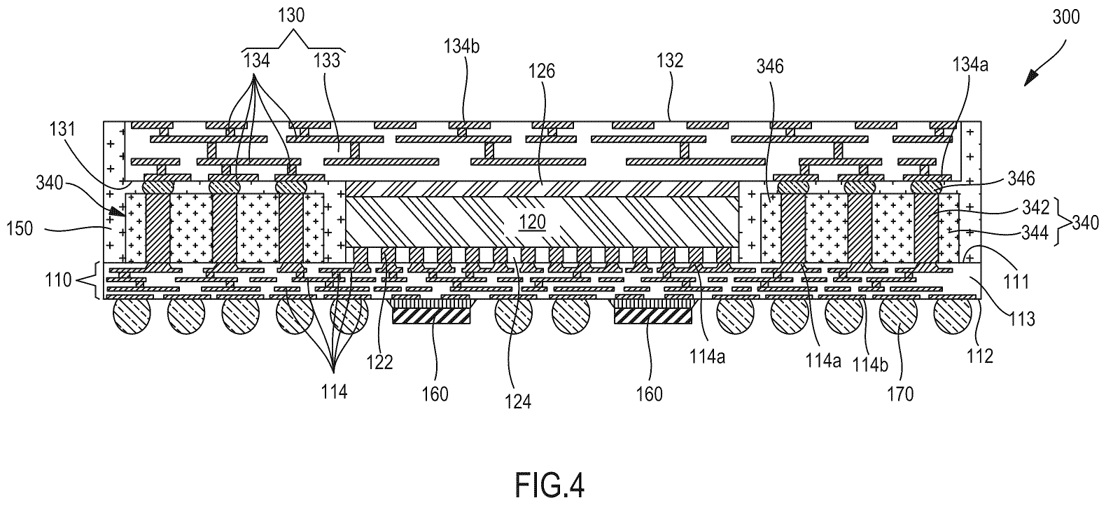

FIG. 4 shows a cross-sectional view of an example electronic device 300. Electronic device 300 can be similar to electronic device 100 of FIG. 1, and can include substrate 110, electronic component 120, substrate 130, encapsulant 150, electronic components 160, and external interconnects 170 as previously described.

In accordance with various examples, electronic device 300 includes internal interconnects 340. In some examples, internal interconnects 340 can be referred to as internal interconnect structures 340. Internal interconnects 340 can each include a plurality of vertical interconnects 342 and an encapsulant 344 surrounding vertical interconnects 342. Vertical interconnects 342 can be embedded within or laterally surrounded or covered by encapsulant 344 with opposing end sides of vertical interconnects 342 exposed from encapsulant 344. In some examples, internal interconnects 340 can be provided by forming vertical interconnects 342, for example pillars such as plated or preformed copper pillars, vertical wires, or other elongated conductive structures on a temporary carrier, providing encapsulant 344 around the conductive structures, removing the temporary carrier, and singulating the encapsulated vertical interconnects 342 into individual internal interconnects 340. The individual internal interconnects 340 can be located on inner side 131 of substrate 130, for example using pick and place equipment.

In some examples, encapsulant 344 can comprise or be referred to as a mold, dielectric, insulator, or body. For example, encapsulant 344 can comprise a mold, such as an epoxy mold compound (E M C), a resin, a filler-reinforced polymer, a B-stage pressed film or a gel, or an organic or inorganic dielectric material. Encapsulant 344 can be provided by compression molding, transfer molding, liquid body molding, vacuum lamination, paste printing, film-assisted molding, spin coating, lamination, or other suitable encapsulation processes.

In accordance with various examples, verticals interconnects 342 of internal interconnect 340 can be coupled to inner terminal 134a of substrate 130 and inner terminals 114a of substrate 110. In some examples, a conductive interface material 346 can couple verticals interconnects 342 to inner terminals 134a. In some examples, conductive interface material 346 can comprise solder.

In accordance with various examples, electronic device 300 can be manufactured using substantially the same method used to manufacture electronic device 100, as shown in FIGS. 2A-21 discussed above. For example, when manufacturing electronic device 300, internal interconnects 340 comprising vertical interconnects 342 and encapsulant 344 can be coupled to inner terminals 134a on inner side 131 of substrate 130 in place of internal interconnects 140 in FIG. 2A. Removal of the upper portion of encapsulant 150 in FIG. 2F can expose the distal side of vertical interconnects 342 and encapsulant 344 comprising the side opposite conductive interface material 346 and inner side 131 of substrate 130. Encapsulant 150 can be coplanar with the distal side of vertical interconnects 342 and encapsulant 344. Inner terminals 114a of conductive structure 114, as provided in FIG. 2G, can be plated on and/or contacting the exposed distal side of vertical interconnects 342.

The present disclosure includes reference to certain examples described herein. It will be understood by those skilled in the art; however, that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

1. An electronic device, comprising:
a first substrate comprising a first conductive structure;
a first electronic component over a first side of the first substrate and coupled to the first conductive structure;
a second substrate over the first electronic component and comprising a second conductive structure;
an internal interconnect coupled to the first conductive structure and the second conductive structure; and
a first encapsulant between the first substrate and the second substrate and covering a lateral side of the first electronic component and a lateral side of the internal interconnect;
wherein a first one of the first substrate and the second substrate comprises a build-up substrate, and a second one of the first substrate and the second substrate comprises a laminate substrate.

2. The electronic device of claim 1, wherein the first substrate comprises the build-up substrate, the second substrate comprises the laminate substrate, and an active side of the first electronic component is oriented toward the first substrate.

3. The electronic device of claim 1, wherein the internal interconnect comprises a copper post.

4. The electronic device of claim 1, wherein the internal interconnect comprises a vertical wire.

5. The electronic device of claim 4, wherein the internal interconnect includes a head portion coupled to the second conductive structure.

6. The electronic device of claim 1, wherein the internal interconnect comprises a plurality of vertical interconnects and a second encapsulant surrounding the plurality of vertical interconnects.

7. The electronic device of claim 1, wherein the first encapsulant extends over a lateral side of the second substrate and is coplanar with a lateral side of the first substrate.

8. The electronic device of claim 1, wherein at least one of:
a minimum line spacing of the first conductive structure is less than a minimum line spacing of the second conductive structure; or
a minimum line width of the first conductive structure is less than a minimum line width of the second conductive structure.

9. The electronic device of claim 1, wherein the first electronic component is coupled to the second substrate with at least one of a die attach film or an adhesive.

10. The electronic device of claim 1, wherein the internal interconnect is coupled to the first conductive structure and the second conductive structure via a solderless plating.

11. A method manufacturing an electronic device, comprising:
providing a first substrate comprising a first conductive structure;
providing an internal interconnect on a first side of the first substrate and coupled to the first conductive structure;
providing a first electronic component over the first side of the first substrate;
providing a first encapsulant over the first side of the first substrate and covering a lateral side of the first electronic component and a lateral side of the internal interconnect; and
providing a second substrate over the first encapsulant and the first electronic component, wherein the second substrate comprises a second conductive structure, wherein the second conductive structure is coupled to the internal interconnect and the first electronic component;
wherein a first one of the first substrate and the second substrate comprises a build-up substrate, and a second one of the first substrate and the second substrate comprises a laminate substrate.

12. The method of claim 11, wherein the first substrate comprises the laminate substrate, and the second substrate comprises the build-up substrate.

13. The method of claim 11, wherein the internal interconnect comprises a copper post.

14. The method of claim 11, wherein the internal interconnect comprises a vertical wire.

15. The method of claim 11, wherein the internal interconnect comprises a plurality of vertical interconnects and a second encapsulant surrounding the plurality of vertical interconnects.

16. A method manufacturing an electronic device, comprising:
providing a plurality of first substrates over a carrier;
providing an electronic component over each first substrate of the plurality of first substrates;
providing a plurality of internal interconnect structures over each first substrate of the plurality of first substrates;
providing a first encapsulant over the first substrates and covering a lateral side of the first substrates; and
providing a second substrate over the first encapsulant and coupled to the internal interconnect structures and to the electronic component provided over each first substrate; and
singulating through the second substrate and the first encapsulant.

17. The method of claim 16, wherein the first substrates comprise laminate substrates and the second substrate comprises a build-up substrate.

18. The method of claim 16, wherein the internal interconnect structures are coupled to the plurality of first substrates via a solderless plating connection.

19. The method of claim 16, wherein the internal interconnect structures comprise at least one of copper pillars surrounded by a second encapsulant or vertical wires.

20. The method of claim 16, wherein after singulating the first encapsulant is covering the lateral side of the plurality of first substrates and coplanar with a lateral side of the second substrate.
